(19) United States
(12) Patent Application Publication
(10) Pub. No.: US 2008/0024984 A1
(43) Pub. Date: Jan. 31, 2008

(54) External hard drive case

(75) Inventor: Wang-Hsiang Lin, Taipei County (TW)

Correspondence Address: BIRCH STEWART KOLASCH & BIRCH, PO BOX 747, FALLS CHURCH, VA, 22040-0747, US

(73) Assignee: CHERN SHI TECH CO., LTD.

(21) Appl. No.: 11/491,987

(22) Filed: Jul. 25, 2006

(51) Int. Cl. H05K 7/20

(52) U.S. Cl. 361/695

(57) ABSTRACT

The present invention discloses an external hard drive case, which is used to accommodate a hard drive and electrically connects with a computer. The external hard drive case comprises: an inner casing and an outer housing encasing the inner casing. The inner casing has an accommodation room having a circuit board, and the circuit board has a connector and a hard drive connector electrically connecting with the hard drive. Specially, the inner casing has a preformed hole arranged corresponding to the connector. The connector is well aligned to the preformed hole beforehand, and then, the circuit board is locked to the inner casing. Thereby, when the user assembles the inner casing into the outer housing, misalignment will not occur between the connector and the preformed hole. Besides, the yield and the fabrication efficiency are thus promoted, and the fabrication cost is effectively reduced.

### FIELD OF THE INVENTION

The present invention relates to a structure of a hard drive case, particularly to a structure of an external hard drive case, which can electrically connect with a computer to transmit information therebetween.

### BACKGROUND OF THE INVENTION

People nowadays rely on computers more and more, and traditional digital storage media, such as floppy disks, can no more satisfy the demands. Therefore, the so-called “detachable hard drive” appears. A detachable hard drive includes: an accommodation framework installed fixedly inside a computer and having a connector; and a hard drive case accommodated by the accommodation framework and having a corresponding connector. However, the detachable hard drive has the disadvantage that the hard drive case thereof needs a compatible accommodation framework. Once the accommodation framework cannot accommodate the hard drive case, the detachable hard drive cannot work. For portability and compatibility, the manufacturers produce external hard drives, which is without the problem of accommodation framework compatibility. An external hard drive connects to a computer without the accommodation framework but with a bus slot. Thereby, the stored data can be easily transferred to another working environment.

Currently, the new-generation digital storage media, such as the compact flash memory, the Smart Media and the Memory Stick, have gradually replaced the low-capacity floppy disks. With the popularization of computers and digital products, the demanded capacities of digital storage devices also grow day by day. In addition to the dedicated hard drives for computers, the manufacturers also produce various external hard drives to meet the market. As the external hard drive not only has a high storage capacity but also has a high-speed bus interface, such as a USB interface or an IEEE1394 interface, it is highly compatible with computers, consumer electronic products and communication products and can directly and easily exchange data with them; i.e. the external hard drive can work immediately via plugging it to the bus port of a personal computer or a notebook computer.

An external hard drive needs accommodating in a case. Among the external hard drive cases prevailing in the market, some have the convenience of non-screwing assemblage; however, they still have certain defects. Refer to FIG. 1 an exploded view schematically showing the structure of a conventional external hard drive case. As shown in FIG. 1, the conventional external hard drive case 10′ has an inner casing 20′ and an outer housing 30′. The inner casing 20′ has an accommodation room 21′, and the accommodation room 21′ accommodates a circuit board 40 and a hard drive 70. The hard drive 70 electrically connects to a hard drive connector 41 of the circuit board 40 and exchanges information with a computer (not shown in the drawing) via a connector 42 of the circuit board 40. The front side of the inner casing 20′ has a front panel 22′, and the rear side of the inner casing 20′ is open. The outer housing 30′ is a rigid case used to accommodate the inner casing 20′, and a rear panel 31′ is secured to the rear side of the outer housing 30′ with four locking elements 312′. The rear panel 31 ′ has a preformed hole 311′ arranged corresponding to the connector 42. When the inner casing 20′ is assembled into the outer housing 30′, the connector 42 outcrops from the preformed hole 311′ and connects with the I/O port of a computer (not shown in the drawing) via a cable. In assembling the conventional external hard drive case 10′, the circuit board 40 is locked to the accommodation room 21′ of the inner casing 20′ with a fastening element 401 without aligning the connector 42 to the preformed hole 311′. After the rear panel 31′ is locked to the outer housing 30′ with four locking elements 312′ and the inner casing 20′ is assembled into the outer housing 30′, there is usually a misalignment occurring between the connector 42 and the preformed hole 311′. The assemblage can be enforced to obtain the alignment between the connector 42 and the preformed hole 311′ and sold as a qualified product. However, when the user pulls out the inner casing 20′ from the outer housing 30′, places the hard drive 70 in the accommodation room 21 ′ and reassembles the inner casing 20′ into the outer housing 30′, he will find that the misalignment between the connector 42 and the preformed hole 311′ persists. The possible causes for the misalignment include: 1. The inferior design or the wearing of the hole-punching tools; 2. The deviation of the position of the locking holes of the rear panel 31′ or the circuit board 40, or the human error occurring in the locking operation of the rear panel 31′ or the circuit board 40; 3. The deviation occurring in the process of soldering the connector 42 to the circuit board 40; and 4. The tool error of the inner casing 20′ or the outer housing 30′.

As mentioned above, there are so many factors to induce the misalignment between the connector 42 and the preformed hole 311′, which will raise the defective fraction and fabrication cost and reduce the fabrication efficiency. Therefore, the designers and the manufacturers of the external hard drive case eagerly look forward to the solution for the misalignment between the connector 42 and the preformed hole 311′.

### SUMMARY OF THE INVENTION

The primary objective of the present invention is to provide an external hard drive case to solve the abovementioned problems, wherein when the user assembles the inner casing into the outer housing, none misalignment of the connector will occur, and whereby the yield and the fabrication efficiency can be promoted, and the fabrication cost can be effectively reduced.

To achieve the abovementioned objective, the present invention proposes an external hard drive case, which is used to accommodate a hard drive and electrically connects with a computer. The external hard drive case comprises: an inner casing and an outer housing encasing the inner casing. The inner casing has an accommodation room. A circuit board is disposed inside the accommodation room and has a connector and a hard drive connector. The external hard drive case of the present invention is characterized in: the inner casing has a preformed hole arranged corresponding to the connector, and information is transmitted between the connector and a computer through the preformed holes.

### BRIEF DESCRIPTION OF THE DRAWINGS

FIG. 1 is an exploded view schematically showing the structure of a conventional external hard drive case.

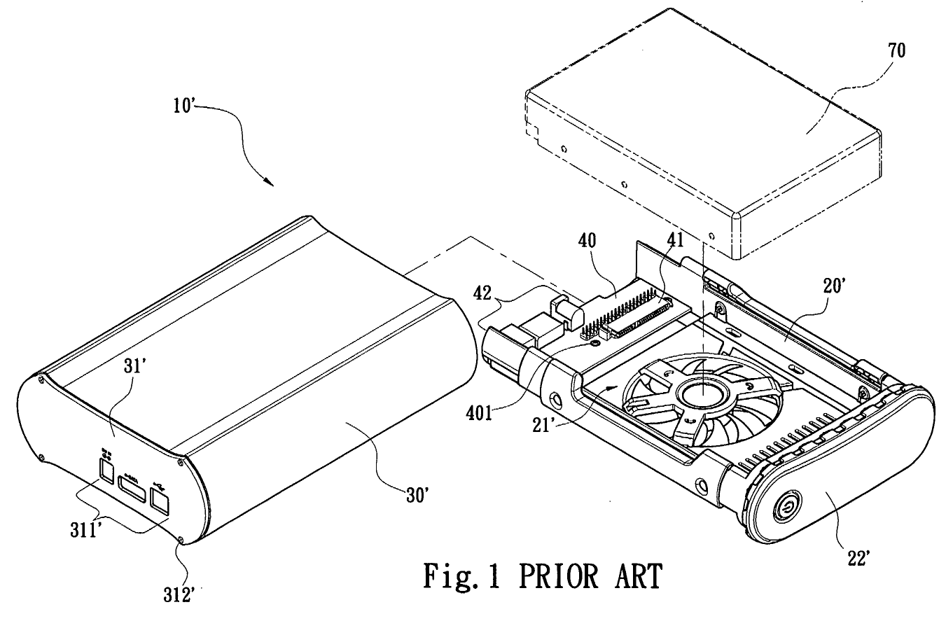

FIG. 2 is an exploded view schematically showing the structure of the external hard drive case according to the present invention.

FIG. 3 is an exploded view schematically showing a portion of the structure of the external hard drive case according to the present invention.

FIG. 4 is a perspective back view schematically showing the appearance of the external hard drive case according to the present invention.

### DETAILED DESCRIPTION OF THE PREFERRED EMBODIMENTS

The technical contents of the present invention are to be described in cooperation with the attached drawings below.

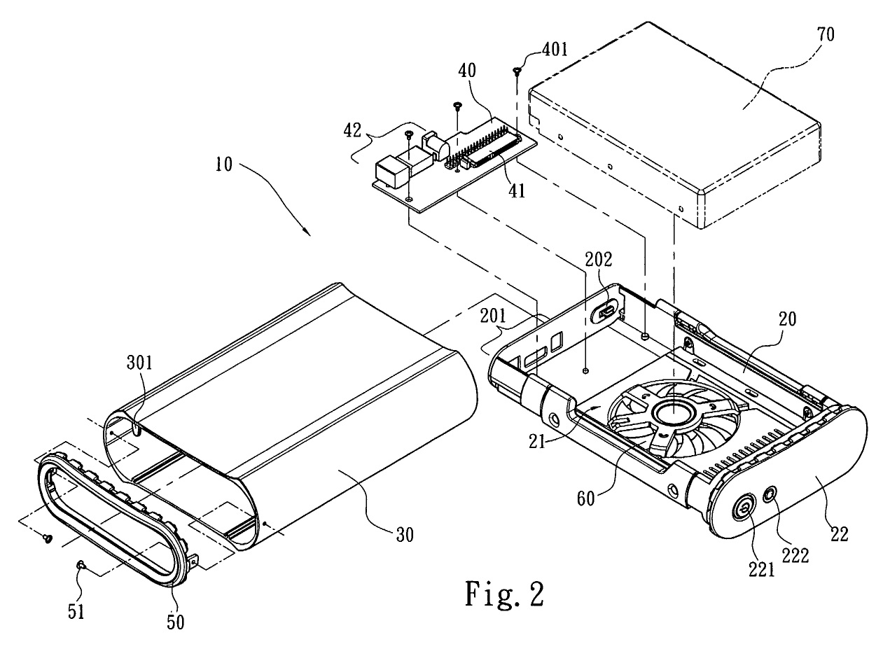

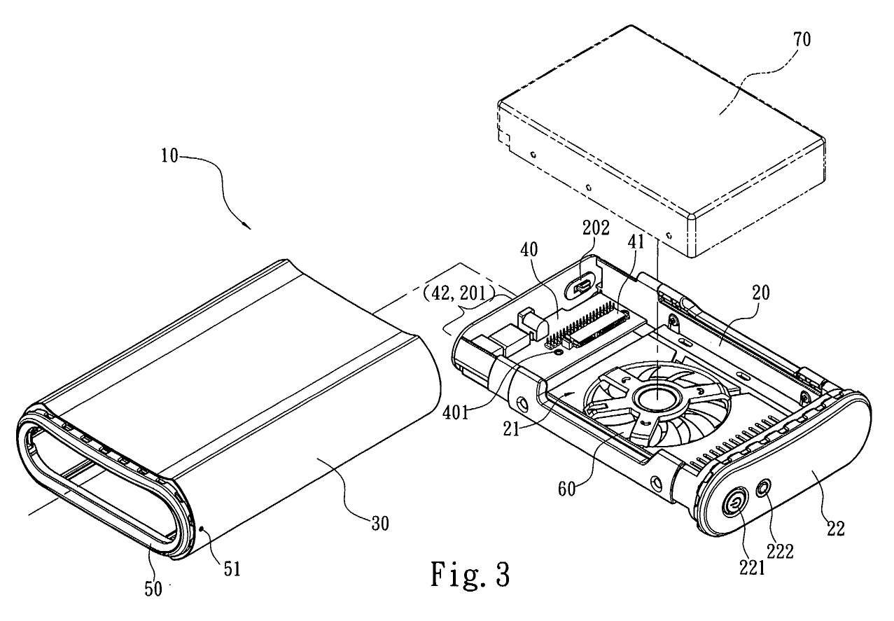

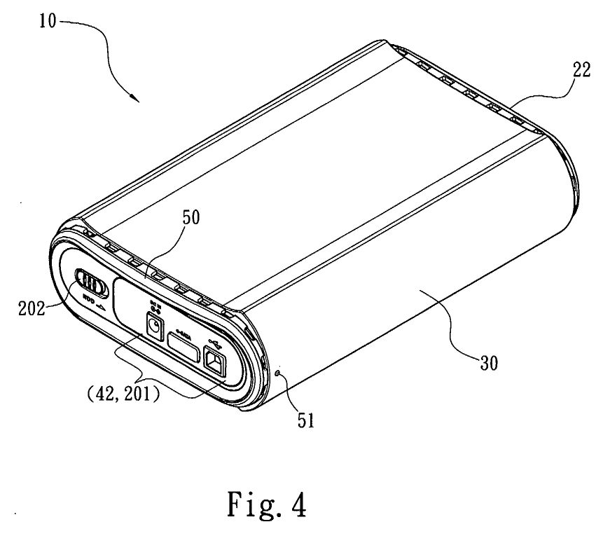

Refer to FIG. 2 an exploded view schematically showing the structure of the present invention, FIG. 3 an exploded view schematically showing a portion of the structure of the present invention, and FIG. 4 a perspective back view schematically showing the appearance of the present invention. As shown in the drawings, the external hard drive case 10 of the present invention is used to accommodate a hard drive 70 and electrically connects with a computer (not shown in the drawings). The external hard drive case 10 comprises: an inner casing 20 and an outer housing 30 encasing the inner casing 20. The inner casing 20 has an accommodation room 21, and an electric fan 60 is disposed on the bottom of the inner casing 20. The accommodation room 21 also has a circuit board 40, and the circuit board 40 has a hard drive connector 41 electrically connecting with the hard drive 70 and a connector 42. The connector 42 can be a USB socket, an IEEE1934 socket, or a power socket; the connector 42 may also be a combination of the abovementioned sockets. Specially, the inner casing 20 has a preformed hole 201 arranged corresponding to the connector 42, and information is transmitted between the connector 42 and a computer (not shown in the drawings) through the preformed holes 201. It is to be noted: the connector 42 has been well aligned to the preformed hole 201 beforehand during fabrication, and then, the circuit board 40 is locked to the accommodation room 21 of the inner casing 20 with locking elements 401. The locking elements 401 can be screws. Therefore, when the inner casing 20 is assembled into the outer housing 30, none misalignment will occur; when the user has placed the hard drive 70 in the inner casing 20 and assembles the inner casing 20 into the outer housing 30, misalignment will not occur between the connector 42 and the preformed hole 201 either.

A decoration ring 50 is secured to the outer housing 30 with fixing elements 51, and the fixing elements 51 may be bolts, rivets, or screws. The decoration ring 50 is used to protect the edge of the rear side of the outer housing 30 and to prettify the external hard drive case 10. The inner casing 20 also has a front panel 22 in the side opposite to the preformed hole 201. The front panel 22 has a start button 221 and a restart button 222, which electrically connect with the circuit board 40. The start button 221 is used to turn on/off the power of the hard drive 70, and the restart button 222 is used to pause and restart the hard drive 70 when the power of the hard drive 70 is turned on. A fixing protuberance 301 is installed inside the outer housing 30, and an outer housing fixing knob 202 is correspondingly installed on the inner casing 20; when the inner casing 20 is assembled into the outer housing 30, the fixing protuberance 301 will snap-fits with the outer housing fixing knob 202, and the inner casing 20 and the outer housing 30 are thus interlocked. The abovementioned structural design of the present invention can promote the yield and fabrication efficiency and can effectively reduce the fabrication cost.

The preferred embodiments described above are not intended to limit the scope of the present invention but only to exemplify the present invention, and any equivalent modification and variation according to the spirit of the present invention is to be also included within the scope of the present invention.

What is claimed is:

1. An external hard drive case, used to accommodate a hard drive and electrically connects with a computer, and comprising: an inner casing and an outer housing encasing said inner casing, wherein said inner casing has an accommodation room, and said accommodation room has a circuit board, and said circuit board has a connector and a hard drive connector, and characterized in: said inner casing has a preformed hole arranged corresponding to said connector, and information is transmitted between said connector and a computer through said preformed holes.

2. The external hard drive case according to claim 1, wherein a decoration ring is installed to one side of said outer housing.

3. The external hard drive case according to claim 2, wherein said decoration ring is installed to one side of said outer housing with a fixing element.

4. The external hard drive case according to claim 1, wherein said inner casing has a front panel in the side opposite to said preformed hole.

5. The external hard drive case according to claim 4, wherein said front panel has a start button and a restart button.

6. The external hard drive case according to claim 1, wherein said inner casing has an electric fan on the bottom thereof.

7. The external hard drive case according to claim 1, wherein a fixing protuberance is installed inside said outer housing.

8. The external hard drive case according to claim 7, wherein an outer housing fixing knob is installed on said inner casing; said outer housing fixing knob can snap-fits with said fixing protuberance, and said inner casing and said outer housing are thus interlocked.

9. The external hard drive case according to claim 1, wherein said hard drive connector is used to electrically connect with said hard drive.

10. The external hard drive case according to claim 1, wherein said circuit board is locked to said accommodation room of said inner casing with locking elements.
